(19) United States
(12) Patent Application Publication
(10) Pub. No.: US 2024/0407245 A1
(43) Pub. Date: Dec. 5, 2024

(54) DEPOSITION MASK, METHOD FOR MANUFACTURING THE SAME, AND DISPLAY DEVICE MANUFACTURED USING THE SAME

(71) Applicant: Samsung Display Co., LTD., Yongin-si (KR)

(72) Inventors: Jeong Kuk KIM, Yongin-si (KR); Sung Woon KIM, Yongin-si (KR); Sug Woo JUNG, Yongin-si (KR); Sung Won CHO, Yongin-si (KR)

(73) Assignee: Samsung Display Co., LTD., Yongin-si (KR)

(21) Appl. No.: 18/418,645

(22) Filed: Jan. 22, 2024

(30) Foreign Application Priority Data
May 31, 2023 (KR) 10-2023-0069718

(51) Int. Cl. H10K 71/16; H10K 50/11; H10K 59/12

(52) U.S. Cl. CPC H10K 71/166; H10K 50/11; H10K 59/1201

(57) ABSTRACT

A deposition mask, method for manufacturing the same, and display device manufactured using the same. The deposition mask includes a mask substrate including an opening, and a mask pattern disposed on the mask substrate and including multiple hole patterns spaced apart from each other, wherein the mask pattern includes a first portion on the mask substrate, and a second portion protruding from the first portion in a direction opposite to the mask substrate, the second portion includes a first protruding portion and a second protruding portion disposed to be adjacent to the hole patterns, and a recessed portion disposed between the first protruding portion and the second protruding portion, and a height of the recessed portion may be smaller than heights of the first protruding portion and the second protruding portion.

### CROSS-REFERENCE TO RELATED APPLICATIONS

This application claims priority under 35 U.S.C. § 119 from Korean Patent Application No. 10-2023-0069718 filed on May 31, 2023 in the Korean Intellectual Property Office, the entire contents of which are incorporated herein by reference.

### BACKGROUND

### 1. Technical Field

The disclosure relates to a deposition mask, a method for manufacturing the same, and a display device manufactured using the same.

### 2. Description of the Related Art

As an information society develops, the demand for a display device for displaying an image may be increasing in various forms. The display device may be a flat panel display, such as a liquid crystal display, a field emission display, or a light emitting display panel. The light emitting display device may include an organic light emitting diode display device including an organic light emitting diode element as a light emitting element or a light emitting diode display device including an inorganic light emitting diode element such as a light emitting diode (LED) as a light emitting element.

In a self-light emitting display device such as the organic light emitting display device, as a technology for depositing an organic material for each pixel, a fine metal mask (FMM) technique may be used in which a thin metal mask may be brought into close contact with a substrate to deposit the organic material at a desired position.

On the other hand, in manufacturing a thin plate such as an FMM mask, research on an electroforming technique is being actively conducted. The electroforming technique may be a method for immersing an anode body or a cathode body in an electrolyte, and applying power to electro-deposit a metal sheet on a surface of the anode body or the cathode body. Since the electroforming technique may be a method for electro-depositing metal ions (e.g., directly electro-depositing metal ions), the electroforming technique may manufacture very thin sheets, and has an advantage in mass production.

### SUMMARY

Aspects of the disclosure provide a deposition mask having a pattern width with high uniformity and a method for manufacturing the same.

Aspects of the disclosure also provide a deposition mask having ultra-high resolution, a method for manufacturing the same, and a display device manufactured using the same.

However, aspects of the disclosure may not be restricted to those set forth herein. The above and other aspects of the disclosure will become more apparent to one of ordinary skill in the art to which the disclosure pertains by referencing the detailed description of the disclosure given below.

According to an aspect of the disclosure, there may be provided a deposition mask that may include a mask substrate including an opening, and a mask pattern disposed on the mask substrate and including a plurality of hole patterns spaced apart from each other, wherein the mask pattern may include a first portion on the mask substrate, and a second portion protruding from the first portion in a direction opposite to the mask substrate, the second portion may include a first protruding portion and a second protruding portion disposed adjacent to the plurality of hole patterns, and a recessed portion disposed between the first protruding portion and the second protruding portion, and a height of the recessed portion may be smaller than heights of the first protruding portion and the second protruding portion.

In an embodiment, the first portion may have a reverse-tapered shape.

In an embodiment, the first portion may include a first surface positioned close to the mask substrate, a second surface positioned on an opposite side of the first surface, and a first side surface disposed between the first surface and the second surface, and a width of the first surface may be greater than a width of the second surface.

In an embodiment, the first side surface may be an inclined surface inclined toward the inside of the first portion from the second surface toward the first surface.

In an embodiment, each of the plurality of hole patterns may have a normal-tapered shape.

In an embodiment, an upper width of each of the plurality of hole patterns may be narrower than a lower width.

In an embodiment, a width of each portion of the plurality of hole patterns positioned between the second portions of the mask pattern may be constant from an upper portion to a lower portion.

In an embodiment, widths of the plurality of hole patterns and widths of the plurality of adjacent hole patterns may be equal.

In an embodiment, the first portion and the second portion may be integral with each other.

In an embodiment, the mask pattern may include at least one of invar, super invar, and nickel.

In an embodiment, the mask substrate may further include an electric field generating part configured to form an electric field.

According to an aspect of the disclosure, there may be provided a method for manufacturing a deposition mask, the method may include forming a mother substrate and a frame including a first material pattern on the mother substrate, a metal pattern on the first material pattern, and a second material pattern on the metal pattern, forming a first metal layer between the frames using an electroforming technique, and forming a mask pattern including the first metal layer and a plurality of hole patterns spaced apart from each other on the mother substrate by removing the frame, wherein the second material pattern includes a tip protruding more than a side surface of the metal pattern.

In an embodiment, the mask pattern may include a first portion positioned on the mother substrate, and a second portion protruding from the first portion in a direction opposite to the mother substrate, the second portion may include a first protruding portion and a second protruding portion disposed adjacent to the plurality of hole patterns, and a recessed portion disposed between the first protruding portion and the second protruding portion, and a height of the recessed portion may be smaller than heights of the first protruding portion and the second protruding portion.

In an embodiment, a width of the metal pattern and a width of an upper surface of the first material pattern may be equal.

In an embodiment, in the forming of the first metal layer, the mother substrate may further include an electric field generating part configured to form an electric field, and the first metal layer may be grown in an upward direction from an upper surface of the mother substrate by the electric field formed by the electric field generating part.

In an embodiment, in the forming of the first metal layer, in case that the first metal layer may be in contact with the metal pattern, the first metal layer may be grown in a horizontal direction from the side surface of the metal pattern.

In an embodiment, in the forming of the first metal layer, in case that the first metal layer may be in contact with the metal pattern, the electric field may be formed by the metal pattern.

In an embodiment, the method may further comprise, forming the second material pattern by patterning a first material layer, forming the metal pattern by patterning a second metal layer using the second material pattern as a mask, and forming the first material pattern by patterning a second material layer using the metal pattern as a mask.

In an embodiment, the method may further comprise forming a mask substrate including an opening by etching a portion of the mother substrate.

According to an aspect of the disclosure, there is provided a display device manufactured using a mask that may include a mask pattern disposed on a mask substrate, the mask substrate may include an opening and the mask pattern may include a plurality of hole patterns spaced apart from each other, the mask pattern may include a first portion positioned on the mask substrate and a second portion protruding from the first portion in a direction opposite to the mask substrate, the second portion may include a first protruding portion and a second protruding portion disposed adjacent to the plurality of hole patterns, and a recessed portion disposed between the first protruding portion and the second protruding portion, and a height of the recessed portion may be smaller than heights of the first protruding portion and the second protruding portion, the display device may include a substrate, a plurality of light emitting elements disposed on the substrate, a pixel defining film configured to partition the plurality of light emitting elements, and a spacer disposed on the pixel defining film, wherein the first protruding portion and the second protruding portion may be configured to be in contact with the spacer.

According to the deposition mask and the method for manufacturing the same according to an embodiment of the disclosure, the pattern width may have high uniformity.

According to the deposition mask, the method for manufacturing the same, and the display device manufactured using the same according to an embodiment of the disclosure, the deposition mask may have ultra-high resolution.

However, the effects of the embodiments may not be restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating an electronic device according to an embodiment;

FIG. 2 is a perspective view illustrating a display device according to an embodiment;

FIG. 3 is a view illustrating an example of a display panel according to an embodiment;

FIG. 4 is a schematic cross-sectional view illustrating a deposition mask according to an embodiment;

FIG. 5 is an enlarged view of part A of FIG. 4;

FIG. 6 is a schematic cross-sectional view illustrating a process of manufacturing a display device using the deposition mask according to an embodiment;

FIG. 7 is a flowchart illustrating a method for manufacturing a deposition mask according to an embodiment;

FIG. 8 is a schematic cross-sectional view illustrating step S100 of FIG. 7;

FIG. 9 is a schematic cross-sectional view illustrating step S200 of FIG. 7;

FIG. 10 is a schematic cross-sectional view illustrating step S300 of FIG. 7;

FIG. 11 is a schematic cross-sectional view illustrating step S400 of FIG. 7;

FIG. 12 is an enlarged view of part B of FIG. 11;

FIG. 13 is a schematic cross-sectional view illustrating step S500 of FIG. 7;

FIGS. 14 and 15 are enlarged views of part C of FIG. 13;

FIG. 16 is a schematic cross-sectional view illustrating step S600 of FIG. 7;

FIG. 17 is a schematic cross-sectional view illustrating step S700 of FIG. 7; and

FIGS. 18 and 19 are schematic cross-sectional views comparing methods for manufacturing a deposition mask according to a comparative example and an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing exemplary features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments of the disclosure will be described in detail with reference to the accompanying drawings.

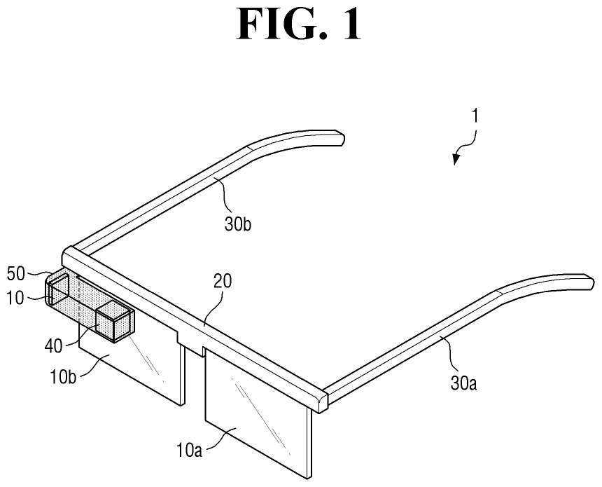

FIG. 1 is a perspective view illustrating an electronic device according to an embodiment.

Referring to FIG. 1, an electronic device 1 according to an embodiment displays a moving image or a still image. The electronic device 1 may refer to any electronic device that provides a display screen. For example, the electronic device 1 may include televisions, laptop computers, monitors, billboards, Internet of things, mobile phones, smartphones, tablet personal computers (PCs), electronic watches, smartwatches, watch phones, virtual reality (VR) devices, augmented reality (AR) devices, mixed reality (MR) devices, extended reality (XR) devices, head mounted displays, mobile communication terminals, electronic notebooks, electronic books, portable multimedia players (PMPs), navigation, game consoles, digital cameras, camcorders, and the like that provide the display screen.

FIG. 1 illustrates an augmented reality (AR) device as an example of the electronic device 1 according to an embodiment. However, the electronic device 1 according to an embodiment may not be limited thereto, and may be any one of a virtual reality (VR) device, a mixed reality (MR) device, and an extended reality (XR) device, and may be any one of the other electronic devices mentioned above. Hereinafter, for convenience of explanation, an example in which the electronic device 1 according to an embodiment may be an augmented reality (AR) device will be described.

The electronic device 1 according to an embodiment may be a glasses-type device. The electronic device 1 may include a display device 10, a left eye lens 10a, a right eye lens 10b, a support frame 20, eyeglass frame legs 30a and 30b, a reflective member 40, and a display device accommodating portion 50.

The display device 10 may provide a display screen. Examples of the display device may include an inorganic light emitting diode display device, an organic light emitting display device, a quantum dot light emitting display device, a plasma display device, and a field emission display device. Hereinafter, an organic light emitting diode display device will be used as an example of the display device, but the disclosure may not be limited thereto and may also be applied to other display devices as long as the same technical idea is applicable thereto.

The left eye lens 10a and the right eye lens 10b may be configured as transparent lenses. For example, the left eye lens 10a and the right eye lens 10b may include a transparent material such as glass or plastic and may be formed to be transparent or translucent. Accordingly, a user may observe a real image through the left eye lens 10a and the right eye lens 10b. In some embodiments, left eye lens 10a and right eye lens 10b may also include refractive lenses configured to correct the user's eyesight. The left eye lens 10a and the right eye lens 10b may be fitted or attached to the support frame 20.

In FIG. 1, the left eye lens 10a and the right eye lens 10b with left and right sides separated are illustrated, but the disclosure may not be limited thereto. For example, the electronic device 1 may also include left and right integrated lenses.

The eyeglass frame legs 30a and 30b may extend to and/or may be connected to the support frame 20. The eyeglass frame legs 30a and 30b may be configured to fix the electronic device 1 to a user's body. For example, the eyeglass frame legs 30a and 30b may include a bent portion so as to be placed over the user's ears.

The electronic device 1 including the eyeglass frame legs 30a and 30b is illustrated in FIG. 1, but the electronic device 1 according to an embodiment may also be a head mounted electronic device including a head mounting band that may be mounted on a user's head instead of the eyeglass frame legs 30a and 30b.

The display device accommodating portion 50 may provide a space in which the display device 10 and the reflective member 40 may be accommodated. An image displayed on the display device 10 may be reflected by the reflective member 40 and provided to a user's right eye through the right eye lens 10b. Accordingly, the user may view a virtual reality image displayed on the display device 10 through the right eye.

It is illustrated in FIG. 1 that the display device accommodating portion 50 may be disposed at a right distal end of the support frame 20, but an embodiment of the specification may not be limited thereto. For example, the display device accommodating portion 50 may be disposed at a left distal end of the support frame 20. An image displayed on the display device 10 may be reflected by the reflective member 40 and provided to a user's left eye through the left eye lens 10a. Accordingly, the user may view a virtual reality image displayed on the display device 10 through the left eye. As an example, the display device accommodating portions 50 may be disposed at both the left and right distal ends of the support frame 20. The user may view a virtual reality image displayed on the display device 10 through both the left and right eyes.

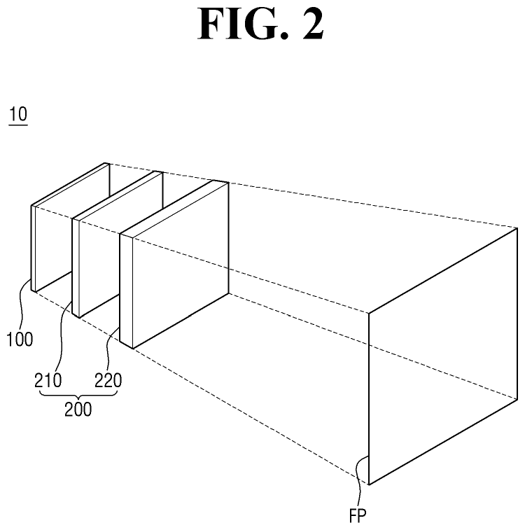

FIG. 2 is a perspective view illustrating a display device according to an embodiment.

Referring to FIG. 2 in addition to FIG. 1, the display device 10 may be an image display module configured to display an augmented reality content image superimposed on a reality image visible to the user. To this end, the display device 10 may include a display panel 100 configured to display an augmented reality content image, and an image transmission member 200 for transmitting the image to the left eye lens 10a and the right eye lens 10b.

The display panel 100 may provide a display screen displaying an image such as the augmented reality content image. Examples of the display panel 100 may include an organic light emitting display panel, a micro LED display panel, a nano LED display panel, a quantum dot light emitting display panel, a liquid crystal display panel, a plasma display panel, a field emission display panel, an electrophoretic display panel, and an electrowetting display panel. Hereinafter, a case where the organic light emitting display panel is applied as an example of the display panel 100 will be described by way of example, but the disclosure may not be limited thereto and may be applied to other display panels as long as the same technical concept is applicable.

The image transmission member 200 may include at least one optical member of an optical waveguide (e.g., a prism), a diffusion lens 210, and a focusing lens 220. Accordingly, the augmented reality content image displayed through the display panel 100 may be provided to a focal plane FP through optical members such as the optical waveguide, the diffusion lens 210, and the focusing lens 220. The focal plane FP may be formed on the left eye lens 10a and the right eye lens 10b or on (e.g., directly on) the user's retina.

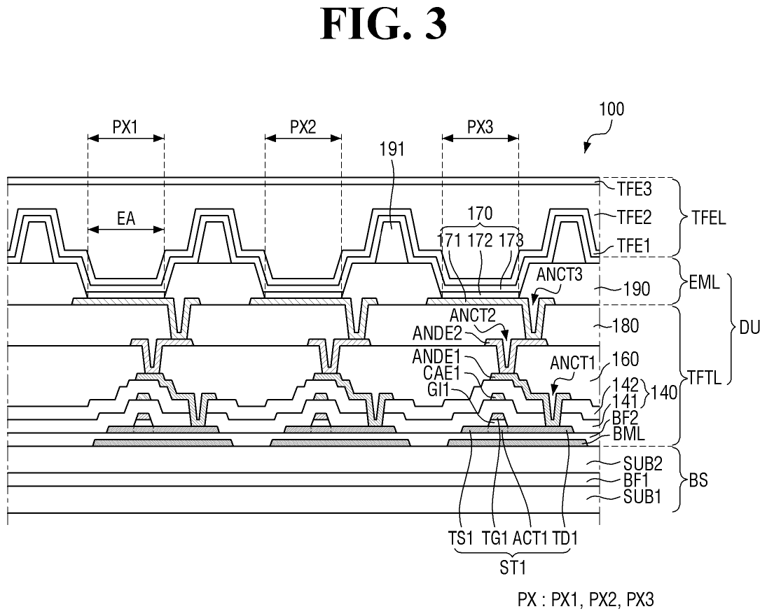

FIG. 3 is a view illustrating an example of a display panel according to an embodiment.

Referring to FIG. 3, the display panel 100 may include a base member BS, a display layer DU, and a thin film encapsulation layer TFEL. The display layer DU may include a thin film transistor layer TFTL and a light emitting element layer EML.

The base member BS may include a first substrate SUB1, a first buffer film BF1 disposed on the first substrate SUB1, and a second substrate SUB2 disposed on the first buffer film BF1.

The first substrate SUB1 and the second substrate SUB2 may be made of an insulating material such as glass, quartz, or polymer resin. Examples of the polymer resin may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. In another example, the substrate may also include a metal material.

The first substrate SUB1 and the second substrate SUB2 may be rigid substrates or flexible substrates that may be bent, folded, and rolled. In case that the substrate may be the flexible substrate, the substrate may be formed of polyimide PI, but may not be limited thereto.

The first buffer film BF1 may be a film for protecting a first thin film transistor ST1 and a light emitting layer 172 from moisture permeating through the first and second substrates SUB1 and SUB2, which are vulnerable to moisture permeation. The first buffer film BF1 may be formed of multiple inorganic layers alternately stacked on each other. For example, the first buffer film BF1 may be formed of multiple films in which one or more inorganic films of a silicon nitride layer, a silicon oxynitride layer, a silicon oxide layer, a titanium oxide layer, and an aluminum oxide layer are alternately stacked on each other.

The thin film transistor layer TFTL may include a lower metal layer BML, a second buffer film BF2, a first thin film transistor ST1, a first gate insulating film GI1, a first interlayer insulating film 141, a first capacitor electrode CAE1, a second interlayer insulating film 142, a first anode connection electrode ANDE1, a first organic film 160, a second anode connection electrode ANDE2, and a second organic film 180.

The lower metal layer BML may be disposed on the second substrate SUB2. The lower metal layer BML may be disposed to overlap a first active layer ACT1 of the first thin film transistor ST1 in a thickness direction to prevent leakage current from occurring in case that light may be incident on the first active layer ACT1 of the first thin film transistor ST1. The lower metal layer BML may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof. The lower metal layer BML may be omitted.

The second buffer film BF2 may be disposed on the lower metal layer BML. The second buffer film BF2 may be a film for protecting the first thin film transistor ST1 and the light emitting layer 172 from moisture permeating through the first and second substrates SUB1 and SUB2, which are vulnerable to moisture permeation. The second buffer film BF2 may be formed of multiple inorganic layers alternately stacked on each other. For example, the second buffer film BF2 may be formed of multiple films in which one or more inorganic films of a silicon nitride layer, a silicon oxynitride layer, a silicon oxide layer, a titanium oxide layer, and an aluminum oxide layer are alternately stacked on each other.

The first active layer ACT1 of the first thin film transistor ST1 may be disposed on the second buffer film BF2. The first active layer ACT1 of the first thin film transistor ST1 includes polycrystalline silicon, single crystal silicon, low-temperature polycrystalline silicon, amorphous silicon, or an oxide semiconductor. The first active layer ACT1 of the first thin film transistor ST1 exposed and not covered by the first gate insulating film GI1 may be doped with impurities or ions to have conductivity. Therefore, a first source electrode TS1 and a first drain electrode TD1 of the first active layer ACT1 of the first thin film transistor ST1 may be formed.

The first gate insulating film GI1 may be disposed on the first active layer ACT1 of the first thin film transistor ST1. It is illustrated in FIG. 3 that the first gate insulating film GI1 may be disposed between a first gate electrode TG1 and the first active layer ACT1 of the first thin film transistor ST1, but the disclosure may not be limited thereto. The first gate insulating film GI1 may also be disposed between the first interlayer insulating film 141 and the first active layer ACT1 and between the first interlayer insulating film 141 and the second buffer film BF2. The first gate insulating film GI1 may be formed as an inorganic layer, for example, a silicon nitride layer, a silicon oxynitride layer, a silicon oxide layer, a titanium oxide layer, or an aluminum oxide layer.

The first gate electrode TG1 of the first thin film transistor ST1 may be disposed on the first gate insulating film GI1. The first gate electrode TG1 of the first thin film transistor ST1 may overlap the first active layer ACT1 in the thickness direction. The first gate electrode TG1 of the first thin film transistor ST1 may be formed as a single layer or multiple layers made of any one of molybdenum (Mo), aluminum (Al), chromium (Cr), gold (Au), titanium (Ti), nickel (Ni), neodymium (Nd), and copper (Cu), an alloy thereof, or a combination thereof.

The first interlayer insulating film 141 may be disposed on the first gate electrode TG1 of the first thin film transistor ST1. The first interlayer insulating film 141 may be formed as an inorganic film, for example, a silicon nitride layer, a silicon oxynitride layer, a silicon oxide layer, a titanium oxide layer, or an aluminum oxide layer. The first interlayer insulating film 141 may include multiple inorganic films.

The first capacitor electrode CAE1 may be disposed on the first interlayer insulating film 141. The first capacitor electrode CAE1 may overlap the first gate electrode TG1 of the first thin film transistor ST1 in a third direction (Z-axis direction). Since the first interlayer insulating film 141 has a dielectric constant, a capacitor may be formed by the first capacitor electrode CAE1, the first gate electrode TG1, and the first interlayer insulating film 141 disposed between the first capacitor electrode CAE1 and the first gate electrode TG1. The first capacitor electrode CAE may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof.

The second interlayer insulating film 142 may be disposed on the first capacitor electrode CAE1. The second interlayer insulating film 142 may be formed as an inorganic film, for example, a silicon nitride layer, a silicon oxynitride layer, a silicon oxide layer, a titanium oxide layer, or an aluminum oxide layer. The second interlayer insulating film 142 may include multiple inorganic films.

The first anode connection electrode ANDE1 may be disposed on the second interlayer insulating film 142. The first anode connection electrode ANDE1 may be electrically connected to the first drain electrode TD1 of the first thin film transistor ST1 through a first anode contact hole ANCT1 penetrating through the first interlayer insulating film 141 and the second interlayer insulating film 142 to expose the first drain electrode TD1 of the first thin film transistor ST1. The first anode connection electrode ANDE1 may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof.

The first organic film 160 for planarization may be disposed on the first pixel connection electrode ANDE1. The first organic film 160 may be formed as an organic film made of an acryl resin, an epoxy resin, a phenolic resin, a polyamide resin, a polyimide resin, or the like.

The second anode connection electrode ANDE2 may be disposed on the first organic film 160. The second anode connection electrode ANDE2 may be electrically connected to the first anode connection electrode ANDE1 through a second anode contact hole ANCT2 penetrating through the first organic film 160 to expose the first anode connection electrode ANDE1. The second anode connection electrode ANDE2 may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof.

The second organic film 180 may be disposed on the second anode connection electrode ANDE2. The second organic film 180 may be formed as an organic film made of an acryl resin, an epoxy resin, a phenolic resin, a polyamide resin, a polyimide resin, or the like.

It is illustrated in FIG. 3 that the first thin film transistor ST1 may be formed in a top gate type in which the first gate electrode TG1 may be positioned above the first active layer ACT1, but the disclosure may not be limited thereto. The first thin film transistor ST1 may be formed in a bottom gate type in which the first gate electrode TG1 may be positioned below the first active layer ACT1 or a double gate type in which the first gate electrode TG1 may be positioned both above and below the first active layer ACT1.

The light emitting element layer EML may be disposed on the second organic film 180. The light emitting element layer EML may include light emitting elements 170 and a bank 190. Each of the light emitting elements 170 may include a first light emitting electrode 171, a light emitting layer 172, and a second light emitting electrode 173.

The first light emitting electrode 171 may be formed on the second organic film 180. The first light emitting electrode 171 may be electrically connected to the second anode connection electrode ANDE2 through a third anode contact hole ANCT3 penetrating through the second organic film 180 to expose the second anode connection electrode ANDE2.

The first light emitting electrode 171 may be formed on the second organic film 180. The first light emitting electrode 171 may be electrically connected to the second anode connection electrode ANDE2 through a third anode contact hole ANCT3 penetrating through the second organic film 180 to expose the second anode connection electrode ANDE2.

In a top emission structure in which light may be emitted toward the second light emitting electrode 173 based on the light emitting layer 172, the first light emitting electrode 171 may be formed of a metal material having high reflectance, such as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy may be an alloy of silver (Ag), palladium (Pd), and copper (Cu).

The bank 190 may be formed to partition the first light emitting electrode 171 on the second organic film 180 to define a light emitting area EA. The bank 190 may be formed to cover an edge of the first light emitting electrode 171. The bank 190 may be formed as an organic film such as an acrylic resin, an epoxy resin, a phenolic resin, a polyamide resin, a polyimide resin, or a combination thereof.

Multiple pixels PX may include respective light emitting areas EA. The pixels PX may include multi-color pixels PX including the respective light emitting areas EA for implementing different colors. For example, the pixels PX may include, but may not be limited to, a first pixel PX1 of red, a second pixel PX2 of green, and a third pixel PX3 of blue.

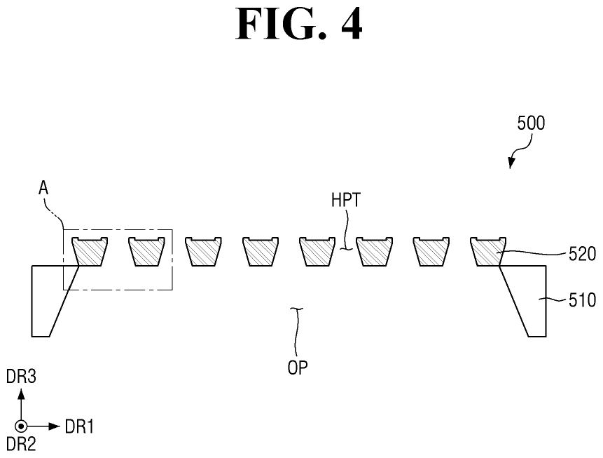

A spacer 191 may be disposed on the bank 190. The spacer 191 may serve to support a mask 500 (see FIG. 4) during a process of manufacturing the light emitting layer 172. The spacer 191 may be formed as an organic film made of an acryl resin, an epoxy resin, a phenolic resin, a polyamide resin, a polyimide resin, the like, or a combination thereof.

The light emitting area EA refers to an area in which the first light emitting electrode 171, the light emitting layer 172, and the second light emitting electrode 173 are sequentially stacked on each other and holes from the first light emitting electrode 171 and electrons from the second light emitting electrode 173 are combined with each other in the light emitting layer 172 to emit light.

The light emitting layer 172 may be formed on the first light emitting electrode 171 and the bank 190. The light emitting layer 172 may include an organic material to emit light of a color. For example, the light emitting layer 172 may include a hole transporting layer, an organic material layer, and an electron transporting layer.

The second light emitting electrode 173 may be disposed on the light emitting layer 172. The second light emitting electrode 173 may be formed to cover the light emitting layer 172. The second light emitting electrode 173 may be a common layer commonly formed in all the light emitting areas EA. Although not illustrated, a capping layer may be formed on the second light emitting electrode 173.

In the top emission structure, the second light emitting electrode 173 may be formed of transparent conductive oxide (TCO) such as indium tin oxide (ITO) or indium zinc oxide (IZO) capable of transmitting light or a semi-transmissive conductive material such as magnesium (Mg), silver (Ag), or an alloy of magnesium (Mg) and silver (Ag). In case that the second light emitting electrode 173 is formed of the semi-transmissive conductive material, light emission efficiency may be increased by a micro cavity.

The thin film encapsulation layer TFEL may be disposed on the second light emitting electrode 173. The thin film encapsulation layer TFEL may include at least one inorganic film to prevent oxygen or moisture from permeating into the light emitting element layer. In addition, the thin film encapsulation layer TFEL may include at least one organic film to protect the light emitting clement layer from foreign substances such as dust. For example, the thin film encapsulation layer TFEL may include a first encapsulation film TFE1, a second encapsulation film TFE2, and a third encapsulation film TFE3.

A first encapsulation film TFE1 (e.g., a first inorganic encapsulation film) may be disposed on the second light emitting electrode 173. The first encapsulation film TFE1 may be an inorganic film of a single layer or multiple layers. The first encapsulation film TFE1 may be formed as multiple films or a single film in which one or more inorganic films of a silicon nitride layer, a silicon oxynitride layer, a silicon oxide layer, a titanium oxide layer, and an aluminum oxide layer are alternately stacked on each other.

A second encapsulation film TFE2 (e.g., a first organic encapsulation film) may be disposed on the first encapsulation film TFE1. The second encapsulation film TFE2 may be an organic film of a single layer or multiple layers. The second encapsulation film TFE2 may include a polymer-based material. Examples of the polymer-based material may include polyethylene terephthalate, polyethylene naphthalate, polycarbonate, polyimide, polyethylene sulfonate, polyoxymethylene, polyarylate, hexamethyldisiloxane, acrylic resin (e.g., polymethyl methacrylate, polyacrylic acid, etc.), or any combination thereof.

A third encapsulation film TFE3 (e.g., a second inorganic encapsulation film) may be disposed on the second encapsulation film TFE2. The third encapsulation film TFE3 may be an inorganic film of a single layer or multiple layers. The third encapsulation film TFE3 may and the first encapsulation film TFE1 may include a same material. For example, the third encapsulation film TFE3 may be formed as multiple films or a single film in which one or more inorganic films of a silicon nitride layer, a silicon oxynitride layer, a silicon oxide layer, a titanium oxide layer, and an aluminum oxide layer are alternately stacked on each other.

Hereinafter, a deposition mask used to manufacture the display device described above will be described.

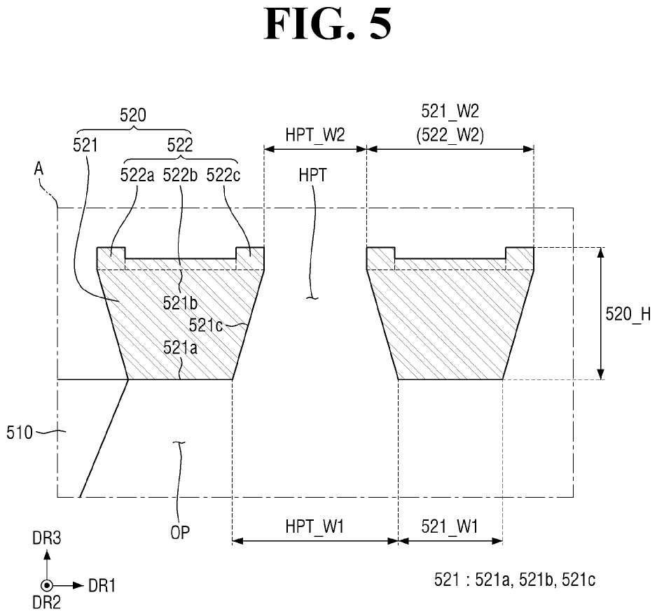

FIG. 4 is a schematic cross-sectional view illustrating a deposition mask according to an embodiment. FIG. 5 is an enlarged view of part A of FIG. 4.

Referring to FIGS. 4 and 5, a deposition mask 500 according to an embodiment may be a mask used for manufacturing an ultra-high resolution display. For example, the deposition mask 500 may be a mask used to manufacture a display included in an extended reality device (XR device) such as a VR device, AR device, or MR device.

In some embodiments, the deposition mask 500 may be used to perform a pixel deposition process on a silicon wafer, which may not be a large-area substrate used in comparative displays. In the case of a display included in the extended reality device, since a screen thereof may be positioned in front (e.g., directly in front) of the user's eyes, the display may have a small screen rather than a large screen. In addition, since the display may be positioned close to the user's eyes, ultra-high resolution may be required. For example, the display included in the extended reality device may require resolution of about 1000 PPI or more, and may require ultra-high resolution of about 2000 PPI or more. The deposition mask 500 according to an embodiment may be a mask used to manufacture such an ultra-high resolution display.

The deposition mask 500 may include a mask substrate 510 and a mask pattern 520. In an embodiment, the deposition mask 500 may be a mask in which the mask pattern 520 may be mounted (e. g., directly mounted) on the mask substrate 510.

The mask substrate 510 may include a silicon wafer. Since the silicon wafer may be processed more finely and precisely than large-area substrates by utilizing technologies developed in semiconductor processing, the silicon wafer may be employed as a substrate of the ultra-high resolution display. The deposition mask 500 according to an embodiment may use the same silicon wafer to form pixels on the silicon wafer of such an ultra-high resolution display.

The mask substrate 510 may have a shape corresponding to the silicon wafer of the ultra-high resolution display. For example, the mask substrate 510 may have the same size or shape as the silicon wafer of the ultra-high resolution display.

However, the mask substrate 510 may not be limited thereto, and may also include a large area substrate in an embodiment. For example, the mask substrate 510 may also include materials such as glass, quartz, polymer resin, or a combination thereof.

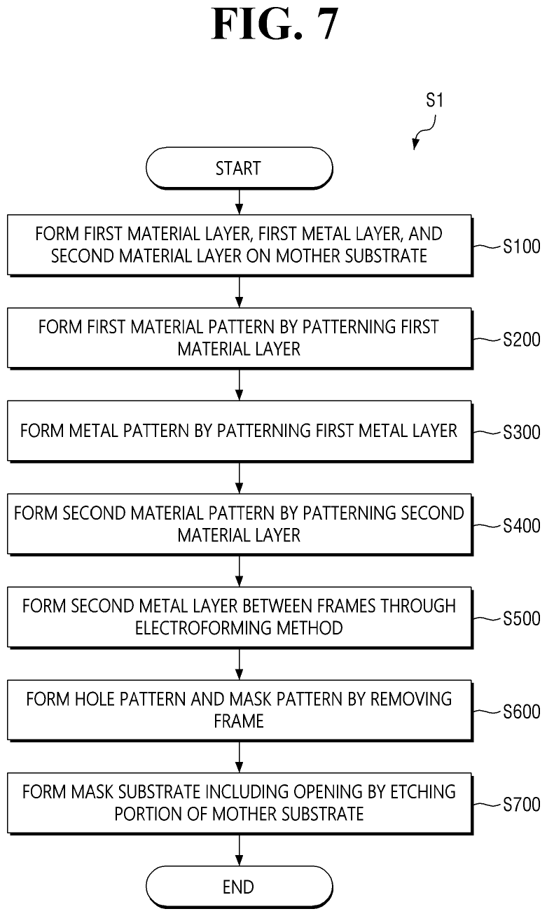

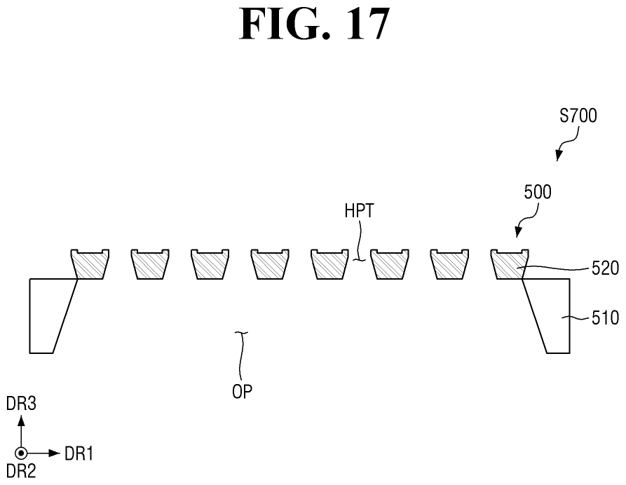

The mask substrate 510 may include a mask opening OP positioned on an opposite side of the mask pattern 520. An inner surface of the mask opening OP may be an inclined surface. For example, the mask opening OP may be formed by etching a portion of a mother substrate MSUB (see FIG. 17) in a method S1 (see FIG. 7) for manufacturing a deposition mask to be described later. In case that wet etching is performed, the inner surface of the mask opening OP may have an inclined surface due to isotropy of an etchant.

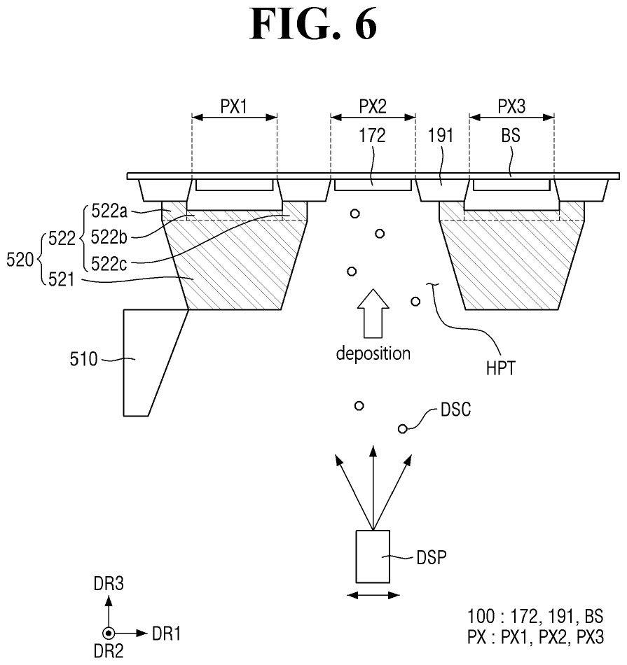

The mask opening OP may provide a passage for evaporated deposition material (or deposition source) DSC (see FIG. 6) to move toward the mask pattern 520. The mask substrate 510 may block the evaporated deposition material DSC (see FIG. 6) in an area other than where the mask opening OP may be positioned.

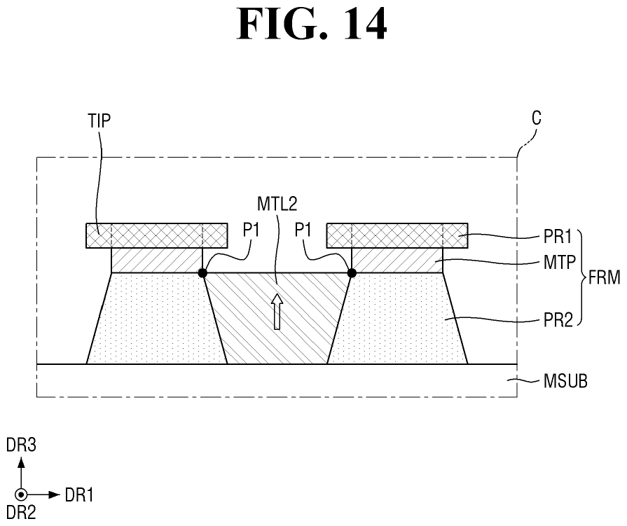

Although not illustrated, the mask substrate 510 may further include an electric field generating part (or electric field former) (not illustrated) configured to form an electric field. The electric field generating part (not illustrated) of the mask substrate 510 may be a wiring or an electrode capable of applying a voltage. The electric field generating part (not illustrated) may form an electric field for using an electroforming technique in a method S1 (see FIG. 7) for manufacturing a deposition mask to be described later. As the electric field generating part (not illustrated) of the mask substrate 510 forms the electric field, a second metal layer MTL2 (see FIG. 14) may be grown from a lower portion of a frame FRM (see FIG. 14).

The mask pattern 520 may include multiple metal patterns spaced apart from each other in the first direction DR1 or the second direction DR2 on a cross section. The metal patterns are spaced apart from each other on the cross section, but may be one mask pattern 520 extended to each other in plan view. Hereinafter, the mask pattern 520 may be a term referring to all of the metal patterns disposed on the mask substrate 510 as a single component, and may be a term referring to a component of each of the metal patterns. For example, the mask pattern 520 may be used interchangeably to refer to an entire group of the metal patterns as a single component or to refer to each of the metal patterns.

In the illustrated drawings, the first direction DR1 and the second direction DR2 are horizontal directions, respectively, and intersect each other. For example, the first direction DR1 and the second direction DR2 may be orthogonal to each other. In addition, a third direction DR3 may be a vertical direction intersecting the first direction DR1 and the second direction DR2, for example, orthogonal to the first direction DR1 and the second direction DR2. In the specification, directions indicated by arrows in the first to third directions DR1, DR2, and DR3 may be referred to as a side, and the opposite direction thereof may be referred to as another side.

The mask pattern 520 may include at least one of invar and super invar. In an embodiment, the mask pattern 520 may also include nickel (Ni). However, the mask pattern 520 may not be limited thereto, and may include a material having a low thermal expansion coefficient and that is magnetic. The mask pattern 520 may have a circular shape in plan view, but may not be limited thereto. A height 520_H of the mask pattern 520 may be in a range of about 1 μm to about 5 μm, but may not be limited thereto.

As illustrated in FIG. 5, the mask pattern 520 may include a first portion 521 and a second portion 522 disposed on the first portion 521. In this specification, the first portion 521 and the second portion 522 may be separately described for convenience of explanation, but the first portion 521 and the second portion 522 may be integral with each other.

The first portion 521 may include a first surface 521a, a second surface 521b positioned on an opposite side of the first surface 521a, and a first side surface 521c disposed between the first surface 521a and the second surface 521b. The first surface 521a may be a surface close to the mask substrate 510, and the second surface 521b may be a surface opposite to the mask substrate 510. The first side surface 521c may be a surface connecting the first surface 521a and the second surface 521b.

The first portion 521 may have a reverse-tapered shape. For example, a width 521_W1 of the first surface 521a may be smaller than a width 521_W2 of the second surface 521b. For example, the first portion 521 may have a narrower width from the second surface 521b toward the first surface 521a. The width 521_W2 of the second surface 521b may be approximately 5 um or less, but may not be limited thereto. The first side surface 521c may be an inclined surface inclined toward the inside of the first portion 521 from the second surface 521b toward the first surface 521a.

The second portion 522 may be disposed on the first portion 521. The second portion 522 may be positioned on the opposite side of the mask substrate 510 with the first portion 521 disposed therebetween. The second portion 522 may have a shape protruding from the first portion 521 in the third direction DR3. The second portion 522 may include a first protruding portion 522a, a recessed portion 522b, and a second protruding portion 522c. A width 522_W2 of the second portion 522 may be the same as the width 521_W2 of the second surface 521b of the first portion 521.

The first protruding portion 522a and the second protruding portion 522c may have shape protruding from the first portion 521. The first protruding portion 522a and the second protruding portion 522c may be spaced apart from each other in the first direction DR1 or the second direction DR2 on the cross section. However, it is illustrated that the first protruding portion 522a and the second protruding portion 522c may be disposed to be spaced apart from each other on the cross section, but in some embodiments, the first protruding portion 522a and the second protruding portion 522c may be components extended to each other in plan view.

The recessed portion 522b may be disposed between the first protruding portion 522a and the second protruding portion 522c. The recessed portion 522b may have a shape recessed toward the first portion 521 rather than the first protruding portion 522a and the second protruding portion 522c. For example, a height of the recessed portion 522b in the third direction DR3 may be smaller than heights of the first protruding portion 522a and the second protruding portion 522c.

The mask pattern 520 may include multiple hole patterns HPT spaced apart from each other between the mask patterns 520 adjacent to each other, for example, the metal patterns adjacent to each other.

The hole patterns HPT may have a normal-tapered shape. This means that an upper width HPT_W2 of the hole patterns HPT may be narrower than a lower width HPT_W1. The upper width HPT_W2 of the hole patterns HPT may be about 2.5 μm or less, but may not be limited thereto. A width of each portion of the hole patterns HPT positioned between the second portions 522 of the mask pattern 520 may be constant from an upper portion to a lower portion.

In some embodiments, all of the hole patterns HPT may overlap the mask opening OP of the mask substrate 510. Accordingly, the evaporated deposition material DSC (see FIG. 6) passing through the mask opening OP may reach the hole patterns HPT.

FIG. 6 is a schematic cross-sectional view illustrating a process of manufacturing a display device using the deposition mask according to an embodiment.

Referring to FIG. 6 in addition to FIGS. 3 to 5, the deposition mask 500 may be used to form the light emitting layer 172 for each pixel PX of the display panel 100. The display panel 100 may be disposed so that the base member BS may be positioned farther from a deposition material supply part DSP. For example, the base member BS may be disposed in an upward direction and the pixel PX may be disposed in a downward direction.

In case that the first to third pixels PX1, PX2, and PX3 may be pixels implementing different colors, a material of a light emitting source included in the light emitting layer 172 of each of the first to third pixels PX1, PX2, and PX3 may be different. For example, the evaporated deposition material DSC for forming the light emitting layer 172 of each of the first to third pixels PX1, PX2, and PX3 may be different.

Therefore, in case that the light emitting layer 172 may be formed on any one of the first to third pixels PX1, PX2, and PX3, the pixel PX on which the light emitting layer 172 may be formed may be disposed to overlap the hole pattern HPT, and the pixel PX on which the light emitting layer 172 may not be formed may be disposed to overlap the mask pattern 520. Accordingly, the evaporated deposition material DSC sprayed from the deposition material supply part DSP may pass through the mask opening OP of the mask substrate 510 and the hole pattern HPT of the mask pattern 520 only in the pixel PX on which the light emitting layer 172 may be formed, and may deposit on the display panel, the mask pattern 520 of the mask 500 being seated on the spacer 191 of the display panel 100.

The deposition mask 500 may be seated on the spacer 191 of the display panel 100. For example, the first protruding portion 522a and the second protruding portion 522c of the second portion 522 may be seated on the spacer 191. The first protruding portion 522a and the second protruding portion 522c of the second portion 522 may be in direct contact with the spacer 191.

Since the deposition mask 500 according to the embodiment includes the first protruding portion 522a, the recessed portion 522b, and the second protruding portion 522c in the second portion 522, a contact area with the spacer 191 may be minimized. Accordingly, occurrence of defects due to contact between the deposition mask 500 and the display panel 100 may be minimized.

In the deposition mask 500 according to the embodiment, the upper width HPT_W2 of the hole patterns HPT may be formed to be the same as the upper width HPT_W2 of the adjacent hole patterns HPT. In order to implement an ultra-high resolution display like the display device 10 described above in FIGS. 1 and 2, the upper width HPT_W2 of the hole patterns HPT needs to be formed to be consistently the same as the upper width HPT_W2 of the adjacent hole patterns HPT. As such, according to the deposition mask 500 according to the embodiment, the deposition mask 500 having high uniformity of a critical dimension CD of the width of the hole patterns HPT may be provided. A method for manufacturing the deposition mask 500 having high uniformity of the critical dimension CD of the width of the hole patterns HPT will be described below.

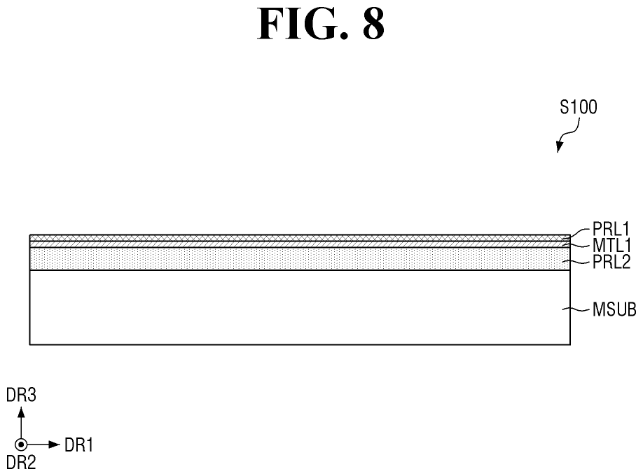

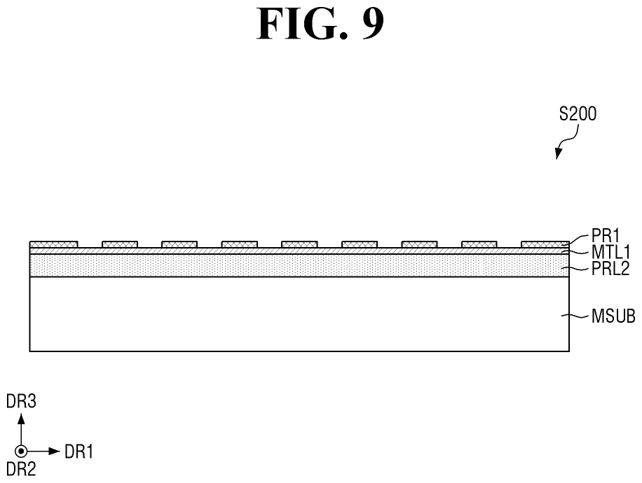

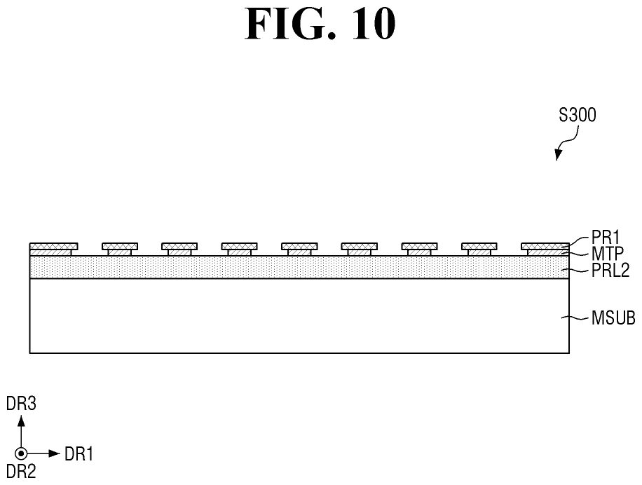

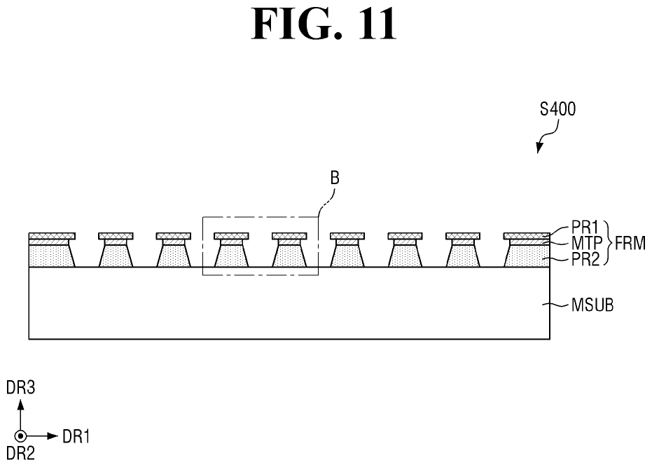

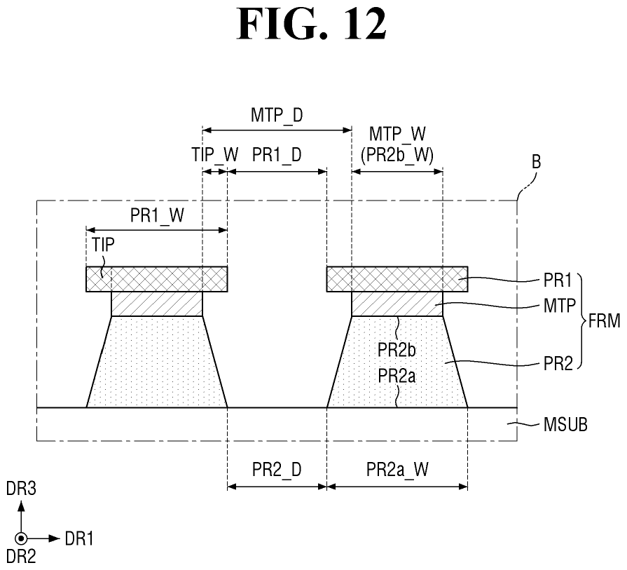

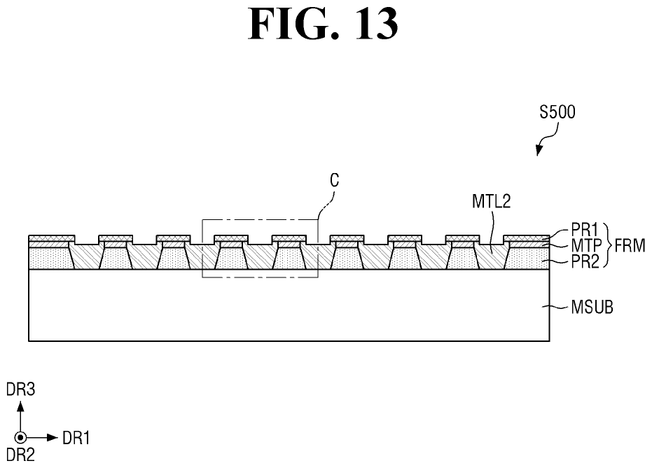

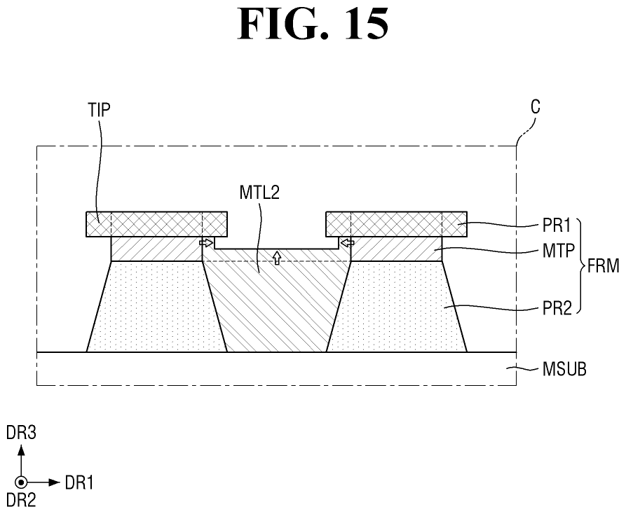

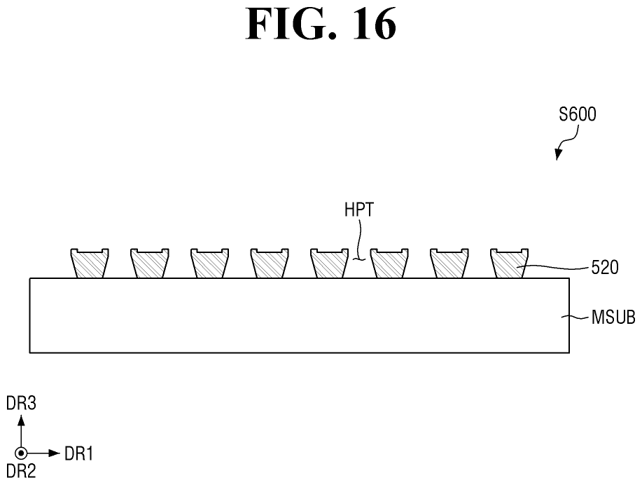

FIG. 7 is a flowchart illustrating a method for manufacturing a deposition mask according to an embodiment. FIG. 8 is a schematic cross-sectional view illustrating step $100 of FIG. 7. FIG. 9 is a schematic cross-sectional view illustrating step S200 of FIG. 7. FIG. 10 is a schematic cross-sectional view illustrating step S300 of FIG. 7. FIG. 11 is a schematic cross-sectional view illustrating step S400 of FIG. 7. FIG. 12 is an enlarged view of part B of FIG. 11. FIG. 13 is a schematic cross-sectional view illustrating step S500 of FIG. 7. FIGS. 14 and 15 are enlarged views of part C of FIG. 13. FIG. 16 is a schematic cross-sectional view illustrating step S600 of FIG. 7. FIG. 17 is a schematic cross-sectional view illustrating step S700 of FIG. 7.

Referring to FIGS. 7 to 17, a method S1 for manufacturing a deposition mask according to an embodiment may include a step (S100) of forming a first material layer, a first metal layer, and a second material layer on a mother substrate, a step (S200) of forming a first material pattern by patterning the first material layer, a step (S300) of forming a metal pattern by patterning the first metal layer, a step (S400) of forming a second material pattern by patterning the second material layer, a step (S500) of forming a second metal layer between frames through an electroforming technique, a step (S600) of forming a hole pattern and a mask pattern by removing the frames, and a step (S700) of forming a mask substrate including a mask opening by etching a portion of the mother substrate.

As illustrated in FIG. 8, in the step (S100) of forming the first material layer, the first metal layer, and the second material layer on the mother substrate, a second material layer PRL2 may be disposed on a mother substrate MSUB, a first metal layer MTL1 may be disposed on the second material layer PRL2, and a first material layer PRL1 may be disposed on the first metal layer MTL1.

The mother substrate MSUB and the mask substrate 510 described above with reference to FIG. 4 may include a same material.

The first material layer PRL1 and the second material layer PRL2 may include a photosensitive material such as photoresist. The first material layer PRL1 and the second material layer PRL2 may include a same material, but may not be limited thereto.

The first metal layer MTL1 may include a metal material having high conductivity and high reactivity to an etchant. For example, the first metal layer MTL1 may be formed as a single layer or multiple layers made of any one of molybdenum (Mo), aluminum (Al), chromium (Cr), gold (Au), titanium (Ti), nickel (Ni), neodymium (Nd), and copper (Cu), an alloy thereof, or a combination thereof.

As illustrated in FIG. 9, in the step (S200) of forming the first material pattern by patterning the first material layer, the first material layer PRL1 may be patterned through exposure and development processes. For example, after a separate exposure mask (not illustrated) may be aligned on the first material layer PRL1, the first material layer PRL1 may be exposed to light such as ultraviolet rays.

In case that the type of photoresist included in the first material layer PRL1 may be positive or negative, a portion exposed to light may dissolve and disappear, or conversely, a portion not exposed to light may dissolve and disappear, by the developer. Accordingly, a first material pattern PRI may be formed.

As illustrated in FIG. 10, in the step (S300) of forming the metal pattern by patterning the first metal layer, the first metal layer MTL1 may be patterned through an etching process using the first material pattern PR1 disposed on the first metal layer MTL1 as a mask. For example, a portion of the first metal layer MTL1 overlapping the first material pattern PRI may not be etched by the etchant, and a portion of the first metal layer MTL1 that does not overlap the first material pattern PR1 may be etched by the etchant. Accordingly, a metal pattern MTP may be formed.

However, in the method S1 for manufacturing the deposition mask according to the embodiment, a portion of the first metal layer MTL1 overlapping the first material pattern PR1 may be further etched. For example, in case that a wet etching process is performed, the etchant may permeate up to a lower portion of the first material pattern PR1 and over-etch the first material pattern PR1. In addition, the first metal layer MTL1 may be over-etched to form a tip protruding more than the metal pattern MTP in the first material pattern PR1.

As illustrated FIG. 11, in the step (S400) of forming the second material pattern PR2 by patterning the second material layer PR2, the second material layer PRL2 may be patterned through exposure and development processes using the metal pattern MTP disposed on the second material layer PRL2 as a mask. For example, a portion of the second material layer PRL2 overlapping the metal pattern MTP may not be exposed to exposure light, and a portion of the second material layer PRL2 that does not overlap the metal pattern MTP may be exposed to exposure light.

In case that the type of photoresist included in the second material layer PRL2 is positive or negative, a portion exposed to light may dissolve and disappear, or conversely, a portion not exposed to light may dissolve and disappear, by the developer. Accordingly, the second material pattern PR2 may be formed.

As illustrated in FIG. 12, the first material pattern PR1, the metal pattern MTP, and the second material pattern PR2 may be included in a frame FRM.

The second material pattern PR2 may have a normal-tapered shape. For example, a width PR2b_W of an upper surface PR2b of the second material pattern PR2 may be smaller than a width PR2a_W of a lower surface PR2a of the second material pattern PR2. For example, the width of the second material pattern PR2 may increase from the upper surface PR2b to the lower surface PR2a. A side surface of the second material pattern PR2 may be an inclined surface that may be inclined outwardly from the upper surface PR2b to the lower surface PR2a.

A side surface of the metal pattern MTP may be a substantially vertical surface. A width MTP_W of the metal pattern MTP may be the same as the width PR2b_W of the upper surface PR2b of the second material pattern PR2. A distance MTP_D between the metal patterns MTP adjacent to each other may be greater than a distance PR2_D between the lower surfaces PR2a of the second material patterns PR2 adjacent to each other.

A side surface of the first material pattern PR1 may be a substantially vertical surface. The first material pattern PR1 may include a tip TIP protruding more than the side surface of the metal pattern MTP. A width PR1_W of the first material pattern PR1 may be greater than the width MTP_W of the metal pattern MTP.

Therefore, a distance PR1_D between the first material patterns PR1 adjacent to each other may be smaller than the distance MTP_D between the metal patterns MTP adjacent to each other. For example, the distance PR1_D between the first material patterns PR1 adjacent to each other may be about 4 μm or less, and the distance MTP_D between the metal patterns MTP adjacent to each other may be about 5 μm or less, but may not be limited thereto. A width TIP_W of the tip TIP may extend by about 0.5 μm beyond an edge of metal pattern MTP on each side, but may not be limited thereto.

As illustrated in FIGS. 13 to 15, in the step (S500) of forming the second metal layer between the frames through the electroforming technique, the second metal layer MTL2 may be formed between the frames FRM on the mother substrate MSUB. The second metal layer MTL2 may be grown between the frames FRM through the electroforming technique.

The second metal layer MTL2 may include at least one of invar, super invar, and nickel. The second metal layer MTL2 may be formed by depositing metal ions from a plating solution containing at least one of invar, super invar, and nickel.

For example, the mother substrate MSUB may include an electric field generating part (not illustrated). The electric field generating part (not illustrated) may be used as a first electrode. A second electrode (not illustrated) opposing the field forming part may be included to form an electric field. The frame FRM may have insulating characteristics to prevent the second metal layer MTL2 from being formed on the frame FRM.

The mother substrate MSUB including the frame FRM and the second electrode (not illustrated) may be immersed in a plating solution. Due to the electric field formed between the first electrode and the second electrode of the field generating part (not illustrated), the second metal layer MTL2 may be grown in a vertical direction from the surface of the mother substrate MSUB between the frames FRM.

As illustrated in FIG. 14, in case that the second metal layer MTL2 grown from the surface of the mother substrate MSUB reaches a boundary point P1 where the second material pattern PR2 and the metal pattern MTP meet, the second metal layer MTL2 may be in contact with the metal pattern MTP. The metal pattern MTP, which was not charged while the second metal layer MTL2 was first grown, may be electrically connected to the electric field generating part (not illustrated) through the second metal layer MTL2 by being in contact with the second metal layer MTL2. Accordingly, the metal pattern MTP may have the same potential as the first electrode.

As illustrated in FIG. 15, the second metal layer MTL2 may also be grown in a horizontal direction on the side surface of the metal pattern MTP having the same potential as that of the first electrode. Accordingly, the same shape as the mask pattern 520 described with reference to FIG. 5 may be formed.

As illustrated in FIG. 16, in the step (S600) of forming the hole pattern and the mask pattern by removing the frames, the frame FRM may be removed. For example, the frame FRM may be removed through a strip process for removing photoresist. At the same time as the second material pattern PR2 may be removed, the metal pattern MTP and the first material pattern PR1 may also be removed together. Accordingly, the second metal layer MTL2 remains on the mother substrate MSUB so that only the mask pattern 520 may be formed, and the hole pattern HPT may be formed at a position where the frame FRM was.

As illustrated in FIG. 17, in the step (S700) of forming the mask substrate including the mask opening OP by etching a portion of the mother substrate MSUB, the mask opening OP may be formed by etching a portion of the mother substrate MSUB overlapping the mask pattern 520.

In some embodiments, the mask opening OP may be formed by a wet etching process. An inclined surface may be formed on a side surface of the mask opening OP due to isotropy.

According to the method S1 for manufacturing the deposition mask according to the embodiment, the deposition mask 500 in which the mask substrate 510 and the mask pattern 520 are integrally formed may be manufactured.

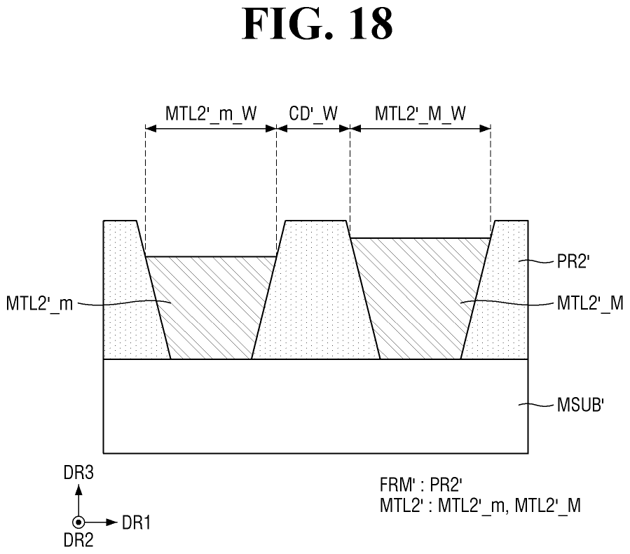

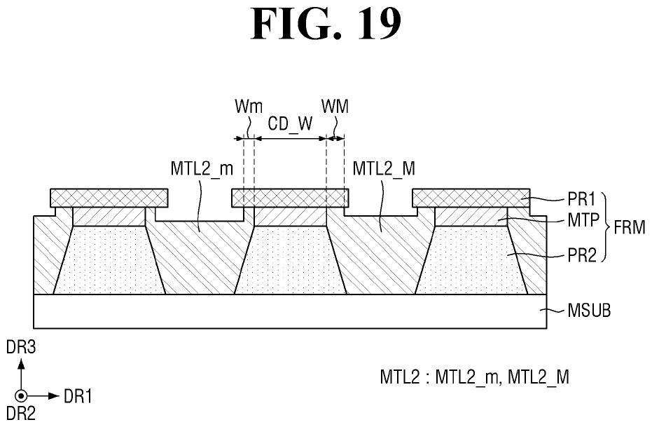

FIGS. 18 and 19 are schematic cross-sectional views comparing methods for manufacturing a deposition mask according to a comparative example and an embodiment. FIG. 18 illustrates a method for manufacturing a deposition mask according to a comparative example, and FIG. 19 illustrates a method for manufacturing a deposition mask according to an embodiment.

Referring to FIGS. 18 and 19, according to the methods for manufacturing a deposition mask according to a comparative example and an embodiment, in case that second metal layers MTL2′ and MTL2 may be formed between frames FRM' and FRM according to the electroforming technique, sizes of the second metal layers MTL2′ and MTL2 grown for each pattern may be different. For example, in case that the second metal layers MTL2′ and MTL2 may be formed according to the electroforming technique, minimum size patterns MTL2′_m and MTL2_m and maximum size patterns MTL2′_M and MTL2_M may be respectively formed.

According to the method for manufacturing the deposition mask according to the comparative example, since the second metal layer MTL2′ includes only the second material pattern PR2′ in case that being grown in a reverse-tapered shape, a maximum width MTL2′_m_W of the minimum size pattern MTL2′_m and a maximum width MTL2′ M W of the maximum size pattern MTL2′_M may be different. Accordingly, since a width CD′_W of a critical dimension formed between the widths varies between each pattern, uniformity of the critical dimension may be lowered.

On the other hand, according to the method for manufacturing the deposition mask according to the embodiment, since the metal pattern MTP and the first material pattern PR1 may be further included on the second material pattern PR2, after the second metal layer MTL2 may be grown in the reverse-tapered shape, a width of the minimum size pattern MTL2_m and a maximum size pattern MTL2_M may be the same.

For example, in the method for manufacturing the deposition mask according to the embodiment, a width Wm of a protruding portion of the minimum size pattern MTL2_m may be smaller than a width WM of a protruding portion of the maximum size pattern MTL2_M. However, since the second metal layer MTL2 may be grown in the horizontal direction on the side surface of the metal pattern MTP, the width of the minimum size pattern MTL2_m and the maximum size pattern MTL2_M may be the same even if the width Wm of the protruding portion of the minimum size pattern MTL2_m may be smaller than the width WM of the protruding portion of the maximum size pattern MTL2_M.

Accordingly, since a width CD_W of a critical dimension formed between the minimum size pattern MTL2_m and the maximum size pattern MTL2_M may be constant between the patterns, uniformity of the critical dimension may be improved. Therefore, reliability as a deposition mask for ultra-high resolution displays may be improved.

In concluding the detailed description, those skilled in the art will appreciate that many variations and modifications can be made to the embodiments without substantially departing from the principles of the disclosure. Therefore, the disclosed embodiments of the invention may be used in a generic and descriptive sense only and not for purposes of limitation.

What is claimed is:

1. A deposition mask comprising:
a mask substrate including an opening; and
a mask pattern disposed on the mask substrate and including a plurality of hole patterns spaced apart from each other, wherein
the mask pattern includes:
a first portion on the mask substrate, and
a second portion protruding from the first portion in a direction opposite to the mask substrate,
the second portion includes:
a first protruding portion and a second protruding portion disposed adjacent to the plurality of hole patterns, and
a recessed portion disposed between the first protruding portion and the second protruding portion, and
a height of the recessed portion is smaller than heights of the first protruding portion and the second protruding portion.

2. The deposition mask of claim 1, wherein the first portion has a reverse-tapered shape.

3. The deposition mask of claim 2, wherein
the first portion includes:
a first surface positioned close to the mask substrate,
a second surface positioned on an opposite side of the first surface, and
a first side surface disposed between the first surface and the second surface, and a width of the first surface is greater than a width of the second surface.

4. The deposition mask of claim 3, wherein the first side surface is an inclined surface inclined toward the inside of the first portion from the second surface toward the first surface.

5. The deposition mask of claim 1, wherein each of the plurality of hole patterns has a normal-tapered shape.

6. The deposition mask of claim 5, wherein an upper width of each of the plurality of hole patterns is narrower than a lower width.

7. The deposition mask of claim 6, wherein a width of each portion of the plurality of hole patterns positioned between the second portions of the mask pattern are constant from an upper portion to a lower portion.

8. The deposition mask of claim 6, wherein widths of the plurality of hole patterns and widths of the plurality of adjacent hole patterns may be equal.

9. The deposition mask of claim 1, wherein the first portion and the second portion are integral with each other.

10. The deposition mask of claim 1, wherein the mask pattern includes at least one of invar, super invar, and nickel.

11. The deposition mask of claim 1, wherein the mask substrate further includes an electric field generating part configured to form an electric field.

12. A method for manufacturing a deposition mask, the method comprising:
forming a mother substrate, and a frame including a first material pattern on the mother substrate, a metal pattern on the first material pattern, and a second material pattern on the metal pattern;
forming a first metal layer between the frames using an electroforming technique; and
forming a mask pattern including the first metal layer and a plurality of hole patterns spaced apart from each other on the mother substrate by removing the frame,
wherein the second material pattern includes a tip protruding more than a side surface of the metal pattern.

13. The method of claim 12, wherein
the mask pattern includes:
a first portion positioned on the mother substrate, and
a second portion protruding from the first portion in a direction opposite to the mother substrate,
the second portion includes:
a first protruding portion and a second protruding portion disposed to be adjacent to the plurality of hole patterns, and
a recessed portion disposed between the first protruding portion and the second protruding portion, and
a height of the recessed portion is smaller than heights of the first protruding portion and the second protruding portion.

14. The method of claim 12, wherein a width of the metal pattern and a width of an upper surface of the first material pattern may be equal.

15. The method of claim 12, wherein
in the forming of the first metal layer, the mother substrate further includes an electric field generating part configured to form an electric field, and
the first metal layer is grown in an upward direction from an upper surface of the mother substrate by the electric field formed by the electric field generating part.

16. The method of claim 15, wherein in the forming of the first metal layer, in case that the first metal layer is in contact with the metal pattern, the first metal layer is grown in a horizontal direction from the side surface of the metal pattern.

17. The method of claim 16, wherein in the forming of the first metal layer, in case that the first metal layer is in contact with the metal pattern, the electric field is formed by the metal pattern.

18. The method of claim 12, further comprising:
forming the second material pattern by patterning a first material layer;
forming the metal pattern by patterning a second metal layer using the second material pattern as a mask; and
forming the first material pattern by patterning a second material layer using the metal pattern as a mask.

19. The method of claim 12, further comprising forming a mask substrate including an opening by etching a portion of the mother substrate.

20. A display device comprising:
a substrate;
a plurality of light emitting elements disposed on the substrate;
a pixel defining film configured to partition the plurality of light emitting elements; and
a spacer disposed on the pixel defining film, wherein
the display device is manufactured using a mask including a mask pattern disposed on a mask substrate, the mask substrate including an opening and the mask pattern including a plurality of hole patterns spaced apart from each other, the mask pattern including a first portion positioned on the mask substrate, and a second portion protruding from the first portion in a direction opposite to the mask substrate, the second portion including a first protruding portion and a second protruding portion disposed adjacent to the plurality of hole patterns, and a recessed portion disposed between the first protruding portion and the second protruding portion, and a height of the recessed portion being smaller than heights of the first protruding portion and the second protruding portion, and
the first protruding portion and the second protruding portion are configured to be in contact with the spacer.
